(19) United States
(12) Patent Application Publication
(10) Pub. No.: US 2006/0090334 A1
(43) Pub. Date: May 4, 2006

(54) Processes for packing memory cards by single mold

(76) Inventors: Chi Hong Chen, Shinchu Hsien (TW); Chen Wen Chuan, Shinchu Hsien (TW); Kuo-Feng Peng, Shinchu Hsien (TW); Chia Jung Chang, Shinchu Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/976,752

(22) Filed: Nov. 1, 2004

(51) Int. Cl. H01L 23/48

(52) U.S. Cl. 29/858; 29/855; 361/719; 257/690

(57) ABSTRACT

Processes for packing -memory cards includes a step of preparing a base circuit board; a step of disposing passing members on the base circuit; a step of installing chips on each of the passive members; a step of using a single mold to glue or mold the chips on the passive members so as to form a plurality of circuit areas; a step of cutting the circuit areas from the base circuit board to be circuit pieces, and a step of installing each of the circuit pieces into casings respectively to obtain memory cards. The processes require only a single mold so as to reduce the expense of the mold and is suitable for mass production.

### FIELD OF THE INVENTION

The present invention relates to processes for packing memory cards by using a single mold.

### BACKGROUND OF THE INVENTION

A conventional method for making memory cards such as SIM cards, multimedia cards and securet digital cards is firstly to cut a circuit board into several parts and each part on which IC chips such as passive chips, flash chips and controller chips are installed. Alternatively, the chips can be glued or molded to form a complete circuit board. However, a specific mold is used to glue or mold one part of the circuit board and this limitation prolongs the operation time. The mold has to be re-built if the shape or specification of the circuit board is changed and this involves high manufacturing cost.

The present invention intends to provide processes for packing memory cares and only a single mold is required to glue or mold the chips on the circuit board. This invention efficiently reduces the cost or the mold and meets the requirements of mass production.

### SUMMARY OF THE INVENTION

The present invention relates to processes for packing memory cards and the processes comprises the following steps:

step 1: preparing a base circuit board;

step 2: disposing passing members on the base circuit;

step 3: installing chips on each of the passive members;

step 4: using a single mold to glue or mold the chips on the passive members so as to form a plurality of circuit areas;

step 5: cutting the circuit areas from the base circuit board to be circuit pieces, and

step 6: installing each of the circuit pieces into casings respectively to obtain memory cards.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows a flow chart of the method of the present invention;

FIGS. 2A to 2F show individual steps of the method of the present invention;

FIGS. 3A to 3C show the molding processes for the circuit pieces;

FIGS. 4A to 4C show the processes of molding, gluing or pressing;

FIGS. 5A and 5B show the base circuit is cut into circuit pieces;

FIGS. 6A and 6B show a side view and a bottom view of the circuit piece, and

FIG. 7 shows the circuit piece is to be installed into a casing.

### DETAILED DESCRIPTION OF THE PREFERRED EMBODIMENT

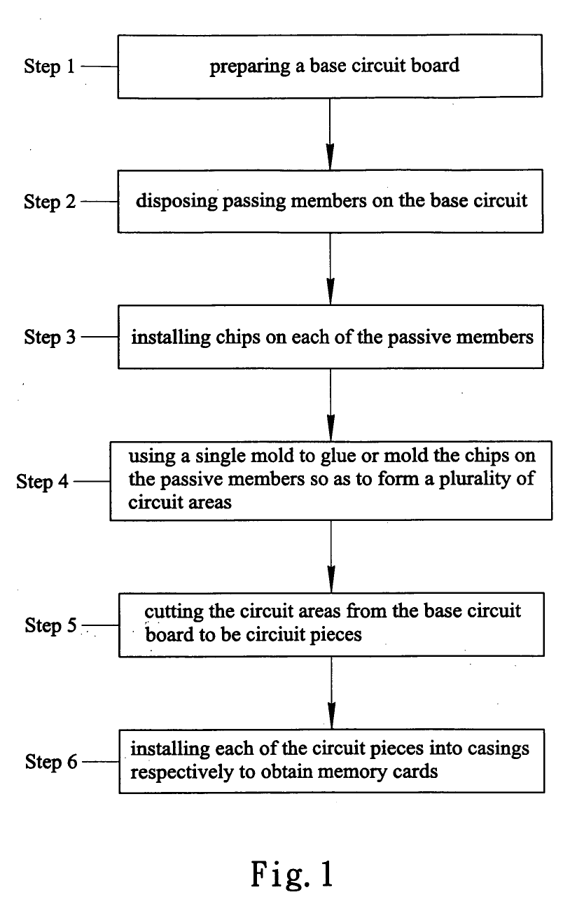

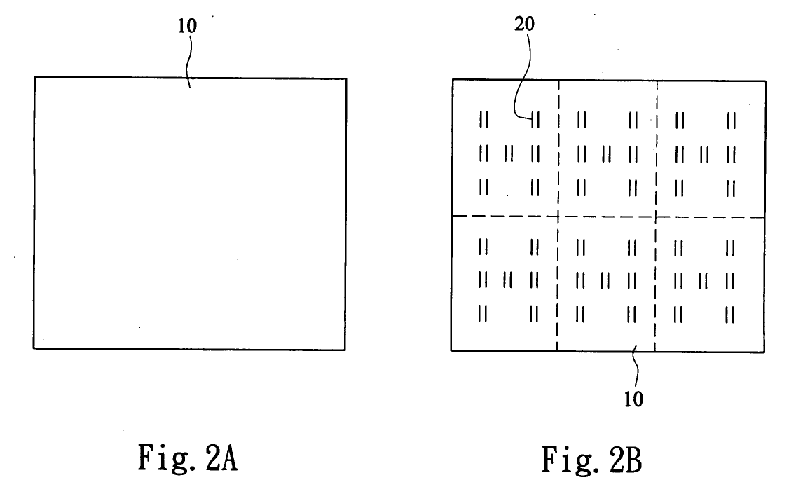

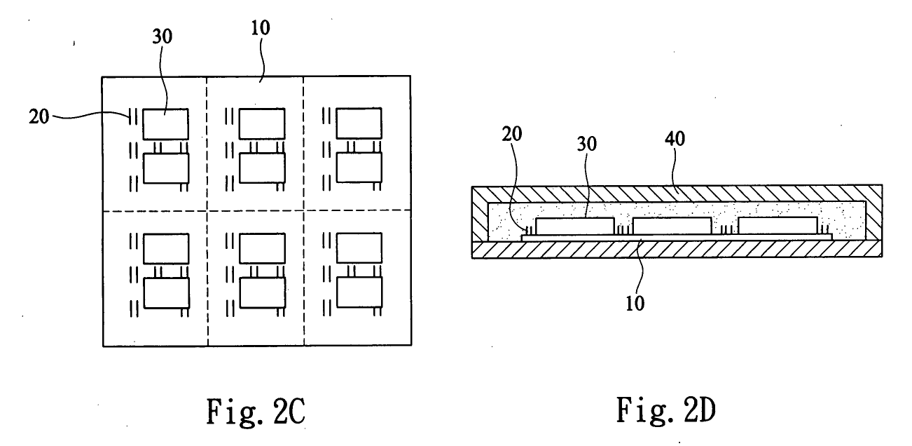

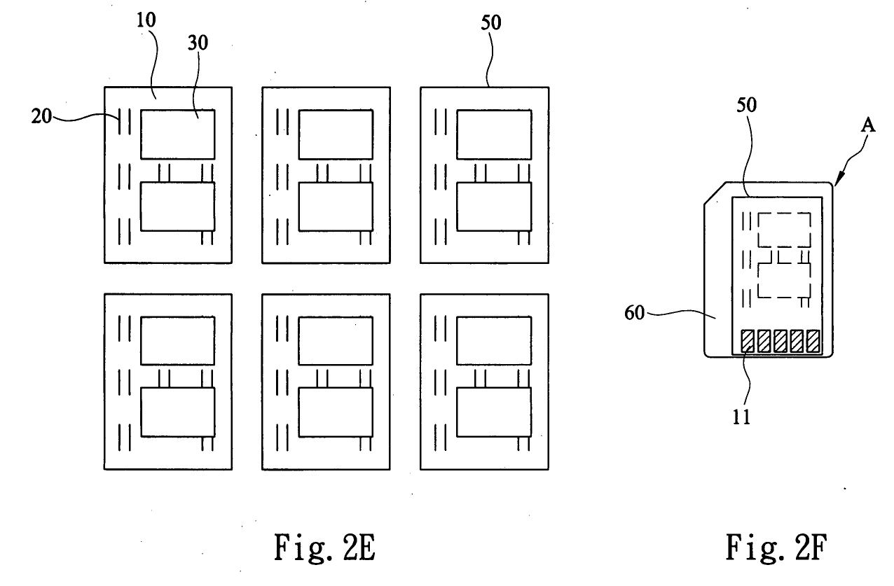

Referring to FIGS. 1 and 2, the processes for packing memory cards “A” such as multimedia cards or securet digital cards, of the present invention comprises the following steps:

step 1: preparing a base circuit board 10 which includes connection ports 11 on back of the base circuit board 10;

step 2: disposing passing members 20 on the base circuit 10;

step 3: installing chips 30, such as flash chips and controller chips, on each of the passive members 20;

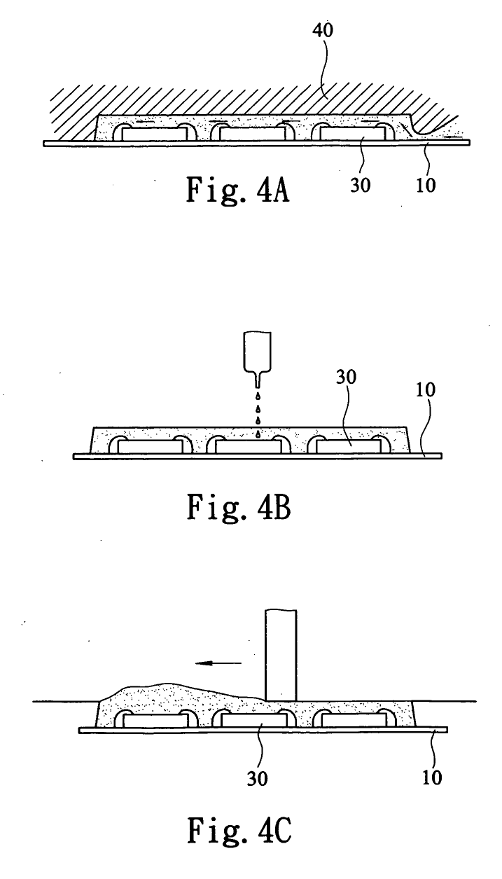

step 4: using a single mold 40 to glue or mold the chips 30 on the passive members 20 as shown in FIGS. 4A to 4C so as to form a plurality of circuit areas;

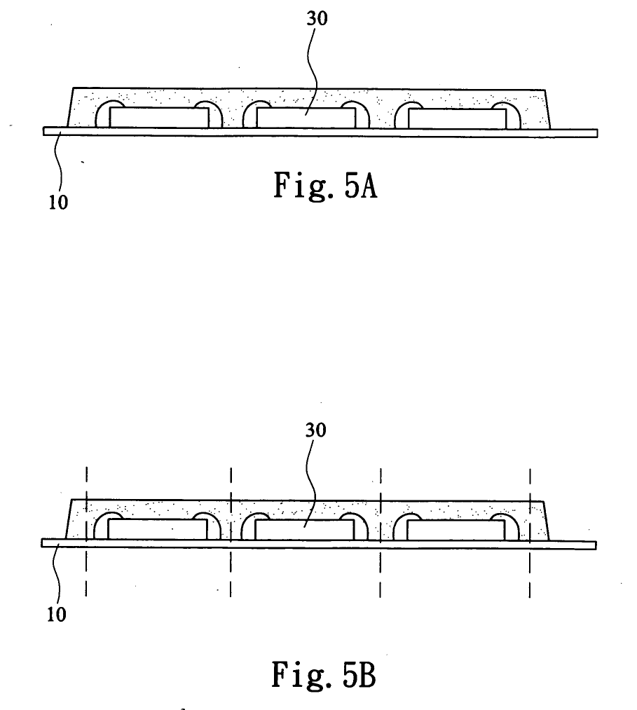

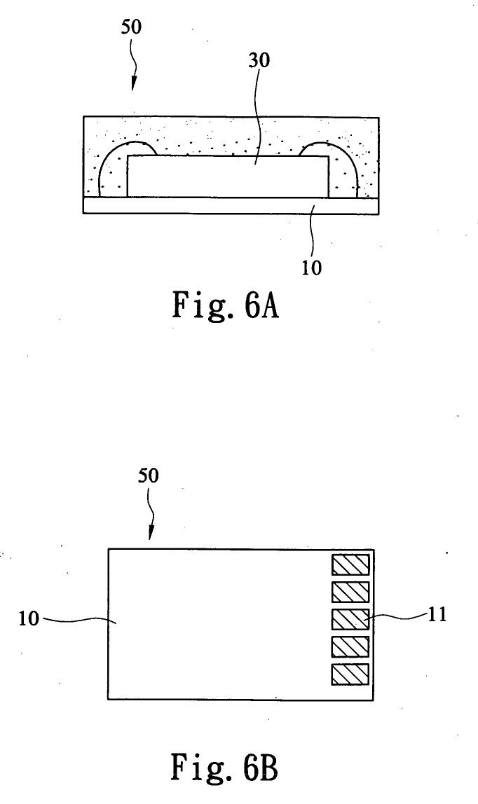

step 5: cutting the circuit areas from the base circuit board 10 to be circuit pieces 50 as shown in FIGS. 5A and 5B, and

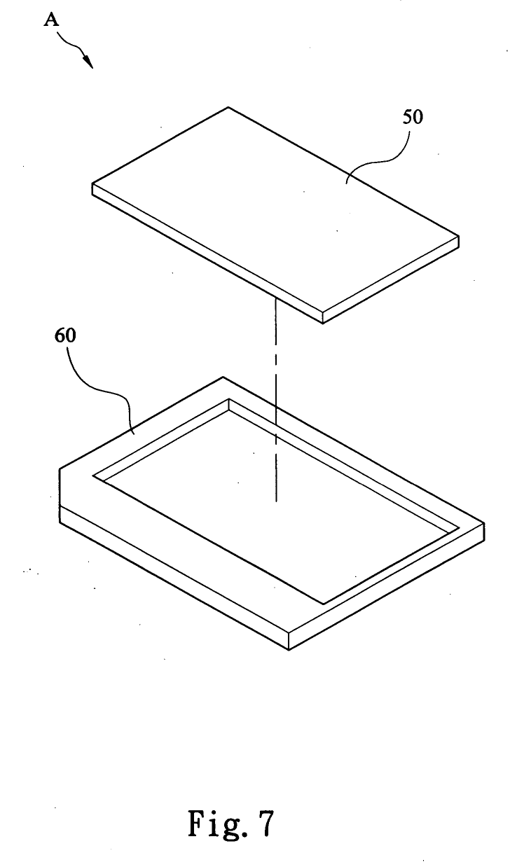

step 6: installing each of the circuit pieces 50 into casings 60 respectively to obtain memory cards “A” as shown in FIG. 7.

The present invention includes the following advantages:

1. The passive members on the base circuit board is glued or molded by a single mold before circuit pieces are cut from the base circuit board so that the expense of the mold can be reduced when compared with the conventional method.

2. The passive members and chips are glued and molded before they are cut into circuit pieces so that the manufacturing speed can be increased and the method is suitable for mass production.

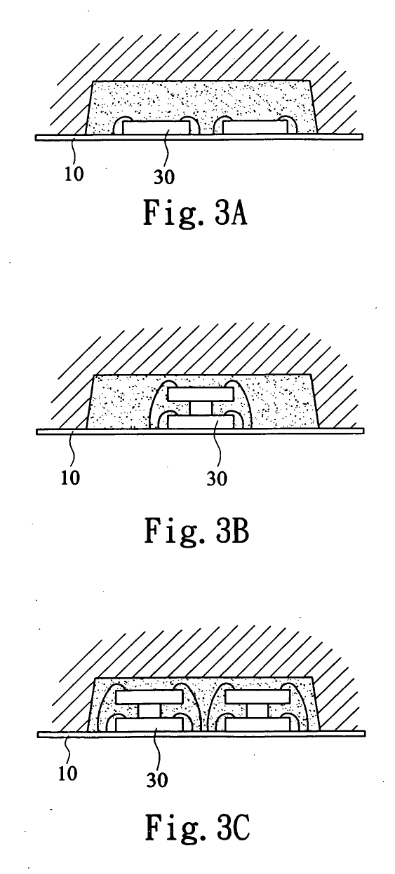

3. All the chips are installed on the circuit areas on the base circuit board and the circuit areas are glued and molded within the same step so that different types of arrangements as shown in FIGS. 3A to 3C can be conveniently controlled. The size of each circuit piece can be made to its maximum range while fit the casing, so that more chips are allowed to be connected to the circuit pieces.

4. Each circuit piece is made as one-piece so that it involves better structural strength and the thickness can be reduced for obtaining better commercial competition.

While we have shown and described the embodiment in accordance with the present invention, it should be clear to those skilled in the art that further embodiments may be made without departing from the scope of the present invention.

What is claimed is:

1. Processes for packing memory cards, comprising:
step 1: preparing a base circuit board;
step 2: disposing passing members on the base circuit;
step 3: installing chips on each of the passive members;
step 4: using a single mold to glue or mold the chips on the passive members so as to form a plurality of circuit areas;
step 5: cutting the circuit areas from the base circuit board to be circuit pieces, and
step 6: installing each of the circuit pieces into casings respectively to obtain memory cards.

2. The processes as claimed in claim 1, wherein the memory cards include multimedia cards, or securet digital cards.

3. The processes as claimed in claim 1, wherein the chips include flash chips and controller chips.
